(19) United States
(12) Patent Application Publication
(10) Pub. No.: US 2023/0202168 A1
(43) Pub. Date: Jun. 29, 2023

(54) Device for Printing to a Recording Medium

(71) Applicant: Canon Production Printing Holding B.V., Venlo (NL)

(72) Inventor: Bernhard Hochwind, München (DE)

(21) Appl. No.: 18/145,243

(22) Filed: Dec. 22, 2022

(30) Foreign Application Priority Data
Dec. 23, 2021 (DE) 10 2021 134 448.4

(51) Int. Cl. B41J 2/045; G01R 31/3183; B41J 29/393

(52) U.S. Cl. CPC B41J 2/04586; G01R 31/318385; B41J 29/393; B41J 2/0451; B41J 2029/3935; B41J 2029/3937

(57) ABSTRACT

A device for printing to a recording medium with an inkjet printing unit that has at least one nozzle arrangement and is designed to generate a print image on the recording medium. The print image includes at least one test pattern that exhibits at least two different spatial frequencies. The device also has an image acquisition unit that is designed to acquire an image of an acquisition region on the recording medium, which acquisition region includes at least a portion of the test pattern; and a processor that is designed to generate image data corresponding to the image and determine a functional state of the nozzle arrangement, by means of the image data, using a neural network.

### CROSS-REFERENCE TO RELATED APPLICATION

This application claims priority to German Patent Application No. 10 2021 134 448.4 filed Dec. 23, 2021, the disclosure of which is hereby incorporated by reference in its entirety.

### BACKGROUND OF THE INVENTION

### Field of the Invention

The invention relates to a device for printing to a recording medium. The device comprises an inkjet printing unit that has at least one nozzle arrangement and is designed to generate a print image on the recording medium.

### Description of Related Art

The inkjet printing unit generates the print image in that it applies ink onto the recording medium from a plurality of nozzles. The number of nozzles is normally very high; at the same time, the nozzles have a small diameter. From this it results that, naturally, a certain number of nozzles are in an improperly functioning state, thus are fouled or filled with air, for example. Often, the arrangement of the nozzles is orthogonal to a feed movement of the recording medium. This leads to the situation that the print image is characterized by streaks at those locations at which the nozzles do not function properly.

Given known devices, a special test pattern is printed in order to identify improperly functioning nozzles. These test patterns are normally constructed so that a pattern of lines with vertical and horizontal pitches that are pre-established and dependent on the arrangement of nozzles is printed by the nozzles, so that which line has been printed by which nozzle can be concluded well from the print result. Which of the nozzles is not functioning properly can then be concluded from the image of the print result. The correct association of the printed lines with the nozzles that are printing them requires a certain regularity of the print pattern. Recognizing the regularity of the print pattern and correctly associating the lines is hindered especially by an optical distortion of the image of the print result, for example due to an objective of a scanner or a deformation of the recording medium. The processing of the image of the print result therefore requires sufficient pitches between the printed lines. Therefore, the test pattern must have a certain size, and can therefore only be accommodated with difficulty into small intervening spaces between print pages. Correspondingly, the test pattern takes up space on the recording medium that cannot be printed to with the actual print image.

Regarding the prior art, refer also to the document DE 10 2019 208 149 A1, which shows a method for detecting defective print nozzles in an inkjet printing machine. In the known method, a detection of the defective print nozzles takes place using a neural network.

### SUMMARY OF THE INVENTION

It is the object of the invention to specify a device for printing to a recording medium that enables a particularly reliable and robust determination of a functional state of a nozzle arrangement of the device. It is also an object of the invention to specify a method for monitoring a functional state of a nozzle arrangement of an inkjet printing unit that is particularly reliable and robust.

This object is achieved via a device having the features as described herein. Furthermore, the object is achieved via the method having the features as described herein. Advantageous developments are specified as described herein.

The proposed device evaluates the test pattern using the neural network. Neural networks are generally based on the physiological processes of perception in biological organisms and are very insensitive to small variations in the input, for example optical distortions, that arise in the acquisition of the image of the detection region. Consequently, in the evaluation of the test pattern, the proposed device is especially insensitive to the distortions intrinsic to the system, and the determination of the functional state of the nozzle arrangement takes place reliably.

The evaluation corresponding to the proposed device does not take place using the regular design of the test pattern, for example in the form of individual lines that are respectively associated with a nozzle. Rather, the neural network evaluates the overall impression of the test pattern. Therefore, it is not necessary to design the test pattern such that individual lines remain distinguishable. The test pattern can accordingly be of very compact design.

The test pattern comprises at least two different spatial frequencies. This means in particular that the test pattern is constructed from at least one coarse structure and at least one fine structure. This simplifies the evaluation by the neural network. Most of all, this allows the neural network to orient in the test pattern, so to speak, and thus to determine an alignment of the test pattern. The neural network can also detect deviation of the printed test pattern from the template and, from this, draw conclusions about the functional state of the nozzle arrangement. The determination of the functional state of the nozzle arrangement thus takes place in a particularly robust manner.

Inputs into the neural network are the image data that correspond to the detection region on the recording medium, as well as image data that correspond to the test pattern. An output of the neural network is the functional state of the nozzle arrangement. For example, an output layer of the neural network may have one neuron for each nozzle of the nozzle arrangement. In this example, the value of each neuron of the output layer corresponds to a functional state of the respective associated nozzle.

A further aspect of the invention relates to a method for monitoring a functional state of a nozzle arrangement of an inkjet printing unit. The method has the same advantages as the device described above, and may especially be developed with the features of the claims dependent on the device claim.

### BRIEF DESCRIPTION OF THE DRAWINGS

Further features and advantages of the invention result from the claims and the following description of preferred embodiments, which are described using the accompanying drawings. Individual features of the embodiments and all combinations thereof, as well as in combination with individual features or feature groups of the preceding specification and/or in combination with individual features or feature groups of the claims with one another in any manner, are deemed disclosed.

Shown are:

FIG. 1 a schematic depiction of a device for printing to a recording medium, according to an exemplary embodiment;

FIG. 2 a schematic depiction of an example of a test pattern of the device according to FIG. 1;

FIG. 3 a schematic depiction of an example of a neural network as is used in the device according to FIG. 1;

FIG. 4 a flow chart of a method for monitoring a functional state of a nozzle arrangement of an inkjet printing device according to an exemplary embodiment.

### DESCRIPTION OF THE INVENTION

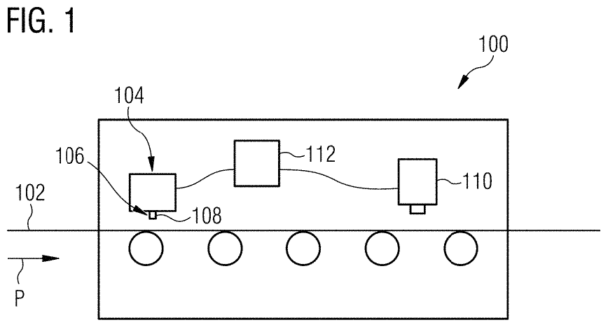

FIG. 1 is a schematic depiction of a device 100 for printing to a recording medium 102, according to an exemplary embodiment.

The device 100 according to FIG. 1 is, by way of example, designed for printing to a recording medium 102 in the form of a belt. In other embodiments, the device 100 is designed for printing to recording media 102 in the form of sheet or page or plate. The recording medium 102 is transported through the device 100 along the transport direction P, which is represented by an arrow. The recording medium 102 may be produced from paper, paperboard, cardboard, metal, plastic, textiles, a combination thereof, and/or other materials that are suitable and can be printed to.

The device 100 comprises an inkjet printing unit 104 having at least one nozzle arrangement 106. The nozzle arrangement 106 comprises a plurality of nozzles 108 that are respectively designed to fire ink droplets onto the recording medium 102, or eject ink droplets in the direction of the recording medium 102, in order to generate dots that form the print image. The nozzle arrangement 106 may, for example, comprise multiple thousands of effectively utilized nozzles 108 that are arranged parallel to the recording medium 102 and transverse to the transport direction P.

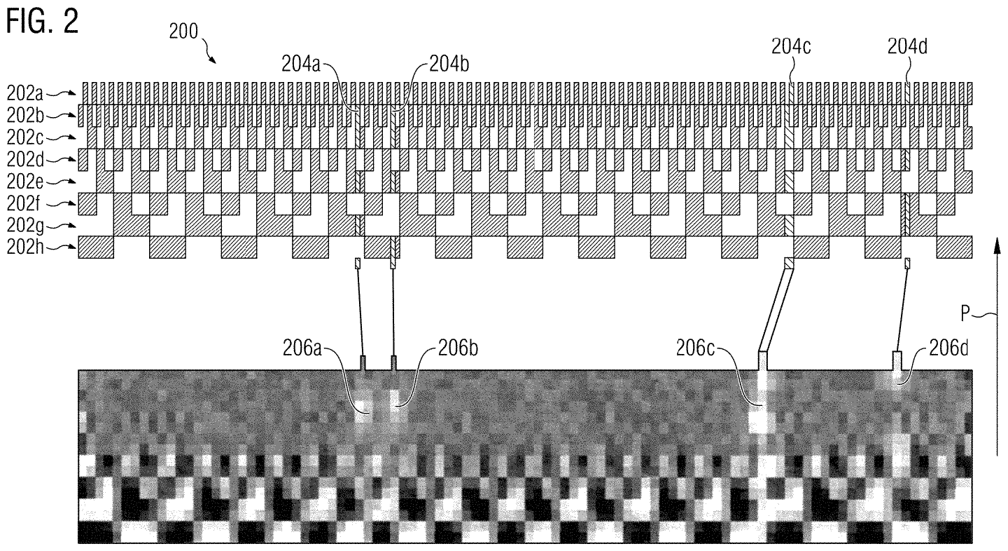

Since the nozzles 108 of the nozzle arrangement 106 are arranged transverse to the transport direction P, the failure of one or more nozzles 108 leads to streaks in the print image. In order to ensure an intended function of the nozzle arrangement 106, the print image comprises a test pattern 200 (see FIG. 2) that is evaluated by the device 100. The test pattern 200 is described in detail in the following using FIG. 2.

To evaluate the test pattern 200, the device 100 comprises an image acquisition [recording] unit 110, for example a scanner unit or a camera. The image acquisition unit 110 is downstream of the nozzle arrangement 106 in the transport direction P and is designed to acquire [record] an image of an acquisition region on the recording medium 102. The acquisition region comprises at least one part of the test pattern 200, but preferably the entire test pattern 200.

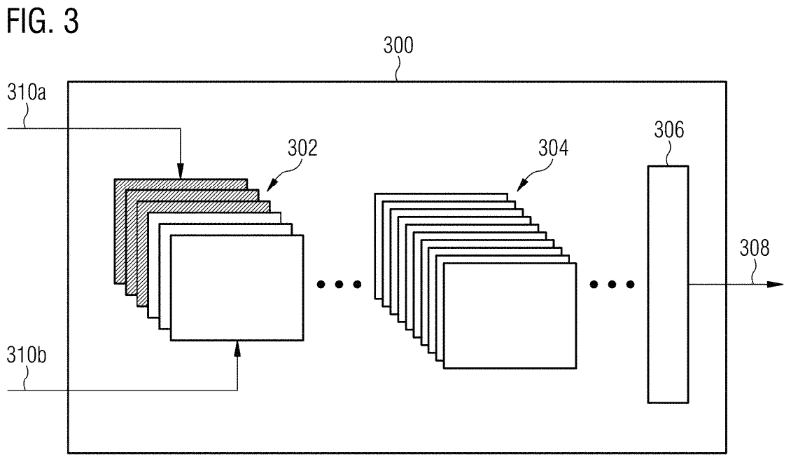

The device 100 also comprises a processor 112 that is connected with the inkjet printing unit 104 and with the image acquisition unit 110. The processor 112 is on the one hand designed to control the inkjet printing unit 104 in order to print the print image onto the recording medium 102 depending on print data. On the other hand, the processor 112 is designed to generate image data corresponding to the image and, by means of the image data, to determine a functional state of the nozzle arrangement 106 using a neural network 300 (see FIG. 3). What is to be understood by the functional state of the nozzle arrangement 106 is in particular whether and which of the nozzles 108 are not functioning as intended. For example, one or more nozzles 108 may not be printing because they are fouled or their nozzle openings are filled with air. Such a failure may be statistically predictable, meaning that a nozzle 108 fails with a certain probability, but generally the failure is unpredictable. However, a failure of a nozzle may also be systemic, meaning that the nozzle fails totally, or in defined and reproducible situations, for example after a defined number of operations without a pause. A functioning of a nozzle 108 that is not as intended may also exist in that the nozzle 108 does not correctly place its dot, or does not set it with the correct size. The determination of the functional state of the nozzle arrangement 106 using the neural network 300 is described in detail in the following using FIG. 3.

FIG. 2 is a schematic depiction of an example of a test pattern 200 of the device 100 according to FIG. 1.

Shown above in FIG. 2 is the test pattern 200 as it is printed on the recording medium 102. The test pattern 200 comprises eight periodic patterns 202a through 202h that are arranged successively in the transport direction P, which travels from bottom to top in FIG. 2. The periodic patterns 202a through 202h have, for example, the same width in the transport direction P and consist of a sequence of printed and unprinted regions that respectively run transverse to the transport direction P. The periodic patterns 202a through 202h essentially form eight lines that follow one another in the transport direction P.

A first line and a second line respectively have a period that corresponds to approximately the width of two nozzles 108.

This means that, in the first two periodic patterns 202a, 202b, the width of a printed or unprinted region respectively corresponds to the width of a nozzle 108. The first two periodic patterns 202a, 202b are arranged such that an unprinted region in the second line follows a printed region in the first line, and vice versa. Regions whose width corresponds to a respective nozzle width and that are periodic in the transport direction P are hereby created in the test pattern 200. A third and fourth line respectively have a period that corresponds to twice the period of the first two lines. The width of a printed or unprinted region of the second two periodic patterns 202c, 202d thus respectively corresponds to two nozzle widths. The third and fourth periodic pattern 202c, 202d are also arranged such that, in the transport direction P, a respective unprinted region follows a printed region, and vice versa. In the following lines, the periods double every two lines, such that the width of a printed or unprinted region of a seventh and eighth line respectively corresponds to eight nozzle widths. Two respective periodic patterns 202a through 202h with the same period are thereby arranged such that, in the transport direction P, the printed regions and the unprinted regions are arranged alternating.

In the shown exemplary embodiment, the various spatial frequencies of the test pattern 200 are realized by the periodic patterns 202a through 202h. The periods of the periodic patterns 202a through 202h thereby respectively correspond to a spatial frequency. The test pattern 200 shown in FIG. 2 is especially optimized for use in inkjet printers. In particular, due to this design, all nozzles 108 of the nozzle arrangement 106 are operated with the same incidence upon generation of the test pattern 200. In particular, the shown test pattern 200 can be continued periodically. The test pattern 200 may hereby be used for different print widths without needing to modify the test pattern 200 for this purpose.

By way of example in the depiction according to FIG. 2, the test pattern 200 has four error regions 204a through 204d. These error regions 204a through 204d are continuously unprinted or incorrectly printed in the transport direction P, and have been generated by improperly functioning nozzles 108. A first, second, and fourth error region 204a, 204b, 204d have respectively been generated by a single improperly functioning nozzle 108. A third error region 204c has been generated by two adjacent improperly functioning nozzles 108.

Shown below in FIG. 2 is the image of the test pattern 200 that the image acquisition unit 110 has acquired. The resolution of the image acquisition unit 110 is lower than the pitch of two dots on the recording medium 102, such that—especially in the first four lines, which correspond to the print lines 202a through 202d—the printed and unprinted regions are no longer distinguishable without taking further measures. However, white regions 206a through 206d are apparent in the image of the test pattern 200 where error regions 204a through 204d occur in said test pattern 200. These white regions 206a through 206d are detected by the neural network 300 and associated with a respective one or more improperly functioning nozzles 108 corresponding to the error regions 204a through 204d.

FIG. 3 is a schematic depiction of an example of a neural network 300 as it is used in the device 100 according to FIG. 1.

The neural network 300 consists of a plurality of layers 302, 304, 306 in succession. With the exception of an input layer 302 and an output layer 306, an output of a layer 304 is an input of a following layer 304. Each of the layers 302, 304, 306 comprises one or more filter kernels. In the shown exemplary embodiment, the input layer 302 has one level for a respective color channel of the template and of the scan of the test pattern. In the convolutional intermediate layers 304, the filter kernels respectively represent different interpretations of the processed image information; for example, a filter kernel may be especially sensitive to vertical edges or rectangular elements of the test pattern 200. The number of filter kernels in the intermediate layers 304 is variable in principle. Upon transitioning from one of the intermediate layers 304 to the next, the activations of the subsequent intermediate layers 304 is calculated by the filter kernels from the activations of the preceding intermediate layers 304. In this way, template and scan of the test pattern 200 are strongly offset against one another.

The layers have a plurality of what are known as neurons, which have a plurality of inputs and typically one or more outputs. The inputs of the neurons are weighted by means of weighting factors, modified by a transfer function of the respective neuron, and finally output. The values of the weighting factors are decisive for the output 308 of the neural network 300. These are established by training the neural network 300 and typically are no longer modified afterward.

Image data 310a that correspond to the acquisition region on the recording medium 102 or to a portion of the recording medium 102, and image data 310b that correspond to the test pattern 200 without the error regions 204a through 204d, are input to the neural network 300 shown in FIG. 3. In addition, an information about the dimensions of an actual printed region on the recording medium 102 may be input to the neural network 300. The output 308 of the neural network 300 is the functional state of the nozzle arrangement 106. The output layer 306 may, for example, have a single neuron whose output indicates whether the nozzle arrangement 106 is functioning properly or not. However, it is advantageous if the output layer 306 has a plurality of neurons that are associated with a corresponding number of nozzles 108 and whose output respectively indicates whether the respective associated nozzles 108 are functioning properly or not.

The output of a neuron of the output layer 306 may be binary, i.e. may indicate whether the nozzle arrangement 106 or individual nozzles 108 are functioning properly or not. However, the output of a neuron of the output layer 306 may also reflect a confidence value that indicates with what probability the nozzle arrangement 106 or individual nozzles 108 are functioning properly or not. In the latter instance, it is assumed that the nozzle arrangement 106 or individual nozzles 108 are not functioning properly if the probability is greater than a predetermined threshold.

The training of the neural network 300 takes place using a training image data set. The training image data set consists of image data that correspond to a plurality of images that have respective different error regions 204a through 204d. These error regions 204a through 204d respectively correspond to improperly functioning nozzles 108 of the nozzle arrangement 106, wherein which error regions 204a through 204d have been generated by which improperly functioning nozzles 108 is known for the training image data set. The training image data set may be generated in that a plurality of print images is generated and acquired with the device 100. Alternating non-functioning nozzles 108 are thereby simulated in that specific nozzles 108 are alternately not activated. Alternatively, the training image data set may also be generated by a simulation of the printing process. It is also possible to post-process the acquired print images in order to, for example, simulate an optical distortion or other variances before they are added to the training image data set (what is known as augmentation).

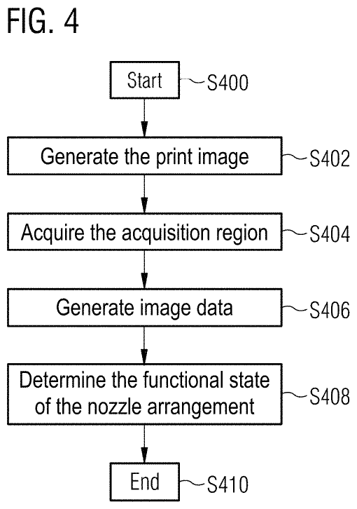

FIG. 4 is a flow chart of a method for monitoring a functional state of a nozzle arrangement 106 of an inkjet printing unit 104 according to an exemplary embodiment.

The method may in particular be implemented with the device 100 according to FIG. 1. The method is started in step S400. In step S402, the print image is generated on the recording medium 102 by means of the inkjet printing unit 104. The print image thereby comprises a test pattern 200 having at least one periodic pattern, in particular the test pattern 200 according to FIG. 2.

In step S404, the image of the acquisition region on the recording medium 102 is detected. The image may comprise the entire test pattern 200. The image may preferably also comprise only a portion of the test pattern 200. Since the test pattern 200 is periodic, the evaluation of the total test pattern 200 is divided up. The computation cost for the neural network 300 is hereby reduced.

In step S406, corresponding image data are generated from the acquired image. In step S408, the functional state of the nozzle arrangement 106 is determined by means of the image data and using the neural network 300. If only a subsection of the test pattern 200 was acquired in step S404, steps S404 through S408 are repeated for the remaining portions of the test pattern 200 in order to determine the functional state of all nozzles 108 of the nozzle arrangement 106. Finally, the method is ended in step S410.

### Reference List

100 device

102 recording medium

104 inkjet printing unit

106 nozzle arrangement

108 nozzle

110 image acquisition unit

112 processor

200 test pattern

202a through 202h pattern

204a through 204d error region

206a through 206d region

300 neural network

302, 304, 306 layer

308 output

310a, 310b image data

P transport direction

1. A device for printing to a recording medium, comprising:
an inkjet printing unit that has at least one nozzle arrangement and is designed to generate a print image on the recording medium,
wherein the print image comprises at least one test pattern that exhibits at least two different spatial frequencies;
an image acquisition unit that is designed to acquire an image of an acquisition region on the recording medium, which acquisition region comprises at least a portion of the test pattern; and
a processor that is designed to generate image data corresponding to the image, and to determine a functional state of the nozzle arrangement based on the image data, using a neural network.

2. The device according to claim 1, wherein the test pattern comprises at least two periodic patterns that respectively have a different period.

3. The device according to claim 1, wherein the inkjet printing unit is designed to move the recording medium along a transport direction upon generating the print image; and wherein the test pattern comprises at least two periodic patterns that are arranged successively in the transport direction and that are respectively periodic in a direction orthogonal to the transport direction.

4. The device according to claim 3, wherein the test pattern has at least one region that comprises a sequence of printed and unprinted regions in the transport direction.

5. The device according to claim 2, wherein the periodic patterns comprise a sequence of printed and unprinted regions.

6. The device according to claim 1, wherein the nozzle arrangement comprises a plurality of nozzles that are designed to eject ink droplets in a direction of the recording medium in order to generate the print image.

7. The device according to claim 6, wherein the processor is designed to determine based on the image data, using the neural network, whether and which nozzles of the nozzle arrangement are not functioning properly.

8. The device according to claim 6, wherein the test pattern is designed such that all nozzles of the nozzle arrangement are used in generating the test pattern.

9. The device according to claim 6, wherein the test pattern is designed such that all nozzles of the nozzle arrangement that are used in the generation of the test pattern are used for the same duration.

10. The device according to claim 6, wherein the inkjet printing unit is designed to move the recording medium along a transport direction upon generating the print image; wherein the test pattern comprises at least two periodic patterns that are arranged successively in the transport direction and are respectively periodic in a direction orthogonal to the transport direction; and wherein the test pattern is designed such that at least two of the nozzles are used to generate a respective one of the two periodic patterns.

11. The device according to claim 1, wherein the acquisition region comprises the entire test pattern.

12. The device according to claim 1, wherein the processor is designed to determine a functional state of the nozzle arrangement, based on the image data and an information about a print width of the print image, using the neural network.

13. The device according to claim 1, wherein the neural network has been trained by training image data that have been generated from images of printed recording media.

14. The device according to claim 1, wherein the neural network has been trained by training image data that have been generated via a simulation of a printing process.

15. A method for monitoring a functional state of a nozzle arrangement of an inkjet printing unit, comprising:
generating a print image on a recording medium, wherein the print image comprises at least one test pattern that exhibits at least two different spatial frequencies;
acquiring an image of an acquisition region on the recording medium that comprises at least a portion of the test pattern;
generating corresponding image data from the image; and
determining the functional state of the nozzle arrangement based on the image data and using a neural network.

16. The method of claim 15, wherein the test pattern comprises at least two periodic patterns that respectively have a different period.

17. The method according to claim 15, further comprising moving the recording medium along a transport direction upon generating the print image; and wherein the test pattern comprises at least two periodic patterns that are arranged successively in the transport direction and that are respectively periodic in a direction orthogonal to the transport direction.

18. The method according to claim 15, wherein the neural network has been trained by training image data that have been generated from images of printed recording media.

19. The method according to claim 15, wherein the neural network has been trained by training image data that have been generated via a simulation of a printing process.

20. The device according to claim 3, wherein the periodic patterns comprise a sequence of printed and unprinted regions.
